(19) United States
(12) Patent Application Publication
(10) Pub. No.: US 2022/0319225 A1
(43) Pub. Date: Oct. 6, 2022

(54) FINGERPRINT SENSING MODULE AND ELECTRONIC APPARATUS

(71) Applicant: Egis Technology Inc., Hsinchu City (TW)

(72) Inventor: Chao-Yi Yeh, Hsinchu City (TW)

(73) Assignee: Egis Technology Inc., Hsinchu City (TW)

(21) Appl. No.: 17/636,896

(22) PCT Filed: Jun. 15, 2020
(86) PCT No.: PCT/CN2020/096153

§ 371 Date: Feb. 21, 2022

Related U.S. Application Data
(60) Provisional application No. 62/896,582, filed on Sep. 6, 2019.

(51) Int. Cl. G06V 40/13; H01L 27/146; G06F 3/041

(52) U.S. Cl. CPC G06V 40/1318; H01L 27/14627; H01L 27/14623; G06F 3/0412

(57) ABSTRACT

An electronic apparatus and a fingerprint sensing module suitable for being arranged below a display panel and including an image sensor disposed below the display panel, microlens array disposed between the image sensor and the display panel and including microlenses arranged in an array, and an ambient light blocking filter disposed between the image sensor and the microlens array and having light channels are provided. Each light channel is surrounded and formed by a light shielding body. Light beams from the microlenses are respectively transmitted to the image sensor through the light channels. The microlens array images a fingerprint of a finger contacting an upper surface of the display panel onto the image sensor, but does not image an electrode structure in the display panel onto the image sensor. The fingerprint sensing module can produce high-contrast fingerprint images and suppress moiré interference, and is less affected by ambient light.

### TECHNICAL FIELD

The invention relates to an optical sensing module and an electronic apparatus, and particularly relates to a fingerprint sensing module and an electronic apparatus.

### RELATED ART

With the development of portable electronic apparatuses (e.g., smartphones, tablet computers, etc.) towards high screen-to-body ratios, conventional capacitive fingerprint sensing modules installed on the front sides of the apparatuses are no longer suitable and have been replaced by under-screen fingerprint sensing modules.

The under-screen fingerprint sensing module may be divided into an ultrasonic fingerprint sensing module and an optical fingerprint sensing module, wherein the optical fingerprint sensing module is more mass-producible and has a lower cost. The conventional optical fingerprint sensing module images a fingerprint image on a display panel onto an image sensor below the display panel through a plurality of lenses arranged on an optical axis, but the optical fingerprint sensing module has the disadvantage of the overly large thickness, which leads to the difficulty in reducing the thickness of the portable electronic apparatus.

In addition, in the conventional optical fingerprint sensing module, the lenses not only image a fingerprint on the display panel onto the image sensor but also image an electrode structure in the display panel onto the image sensor, thus resulting in moiré interference in a fingerprint image sensed by the image sensor and further reducing a success rate and accuracy of fingerprint recognition.

Besides, when the conventional optical fingerprint sensing module senses the fingerprint, ambient light incident obliquely also easily causes the contrast of the fingerprint image to decrease, which poses an impact on the success rate and the accuracy of fingerprint recognition.

### SUMMARY OF THE INVENTION

The invention is directed to a fingerprint sensing module capable of generating a fingerprint image with high contrast and suppressing moiré interference and less subject to ambient light.

An embodiment of the invention provides a fingerprint sensing module that is adapted to be disposed below a display panel and includes an image sensor, a microlens array, and an ambient light blocking filter. The image sensor is disposed below the display panel. The microlens array is disposed between the image sensor and the display panel and includes a plurality of microlenses arranged in an array. The ambient light blocking filter is disposed between the image sensor and the microlens array and has a plurality of light channels, each of which is surrounded and formed by a light shielding body, where light beams coming from the microlenses are respectively transmitted to the image sensor through the light channels. The display panel has an upper surface contacted by a finger of a user, a lower surface facing the image sensor, and an electrode structure located between the upper surface and the lower surface. The microlens array images a fingerprint of the finger contacting the upper surface onto the image sensor but does not image the electrode structure onto the image sensor.

An embodiment of the invention provides an electronic apparatus that includes a display panel and said fingerprint sensing module, where the fingerprint sensing module is disposed below the display panel.

In the fingerprint sensing module and the electronic apparatus provided in the embodiments of the invention, the microlens array is adopted to focus the fingerprint image on the image sensor, and the light shielding body of the ambient light blocking filter is applied to prevent the ambient light with a large incident angle from being transmitted to the image sensor, thereby allowing the image sensor to sense an image with high contrast. In addition, since the microlens array images the fingerprint of the finger contacting the upper surface onto the image sensor but does not image the electrode structure onto the image sensor, the moiré interference in the fingerprint image sensed by the image sensor may be effectively suppressed.

### DESCRIPTION OF THE DRAWINGS

FIG. 1 is a schematic cross-sectional view of an electronic apparatus according to an embodiment of the invention;

FIG. 2 is a schematic top view of the ambient light blocking filter in FIG. 1;

FIG. 3 is a schematic cross-sectional view of an electronic apparatus according to another embodiment of the invention.

### DESCRIPTION OF THE EMBODIMENTS

Reference will now be made in detail to exemplary embodiments of the disclosure, and examples of the exemplary embodiments are illustrated in the accompanying drawings. Whenever possible, the same reference numerals are used in the drawings and descriptions to indicate the same or similar parts.

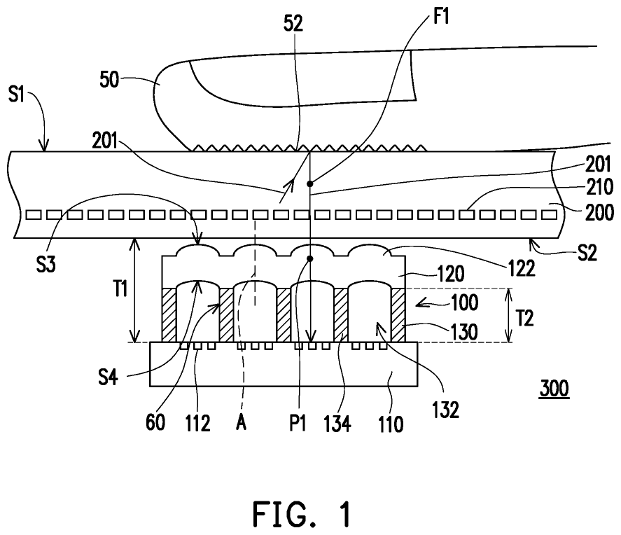

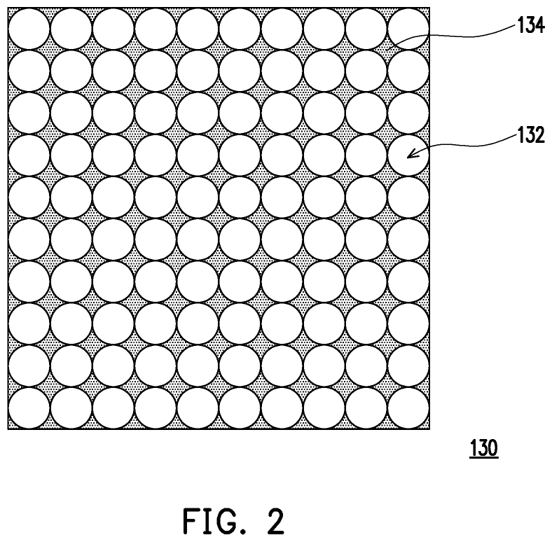

FIG. 1 is a schematic cross-sectional view of an electronic apparatus according to an embodiment of the invention, and FIG. 2 is a schematic top view of the ambient light blocking filter in FIG. 1. Please refer to FIG. 1 and FIG. 2. An electronic apparatus 300 provided in this embodiment includes a display panel 200 and a fingerprint sensing module 100. The fingerprint sensing module 100 is adapted to be disposed below the display panel 200, wherein the display panel 200 is, for instance, a transparent display panel. For instance, the display panel 200 maybe an organic light-emitting diode (OLED) display panel, a liquid crystal display panel, a micro light-emitting diode display panel, or other appropriate transparent display panels.

In this embodiment, the fingerprint sensing module 100 includes an image sensor 110, a microlens array 120, and an ambient light blocking filter 130. The image sensor 110 is disposed below the display panel 200, where the image sensor is, for instance, a complementary metal oxide semiconductor (CMOS) image sensor, a charge coupled device (CCD), a thin film transistor image sensor, or other appropriate image sensors.

The microlens array 120 is disposed between the image sensor 110 and the display panel 200 and includes a plurality of microlenses 122 arranged in an array (e.g., a two-dimensional array). The ambient light blocking filter 130 is disposed between the image sensor 110 and the microlens array 120 and has a plurality of light channels 132, and each of the light channels 132 is surrounded and formed by a light shielding body 134.

A light beam 201 emitted by the display panel 200 irradiates a finger 50 pressing an upper surface (i.e., a surface S1) of the display panel 200, and then the light beam 201 is reflected by the finger 50, penetrates the display panel 200, and is transmitted to the microlens array 120, wherein the light beam 201 reflected by the finger 50 carries information of a fingerprint 52 of the finger 50. The light beam 201 then passes through the microlenses 122, and the light beam 201 coming from the microlenses 122 is transmitted to the image sensor 110 through the light channels 132, respectively.

In this embodiment, the image sensor 110 is a thin film transistor image sensor, which is formed by, for instance, depositing a thin film on a glass substrate to form a thin film transistor and a photodiode. In addition, the thin film transistor sensor may fully cover a bottom portion of the entire display panel 200 to achieve full-screen fingerprint sensing effects. However, in other embodiments, the image sensor 110 may also be located below a partial region (e.g., a fingerprint sensing region) of the display panel 200, and the image sensor 110 may be a conventional semiconductor image sensor formed on a silicon substrate.

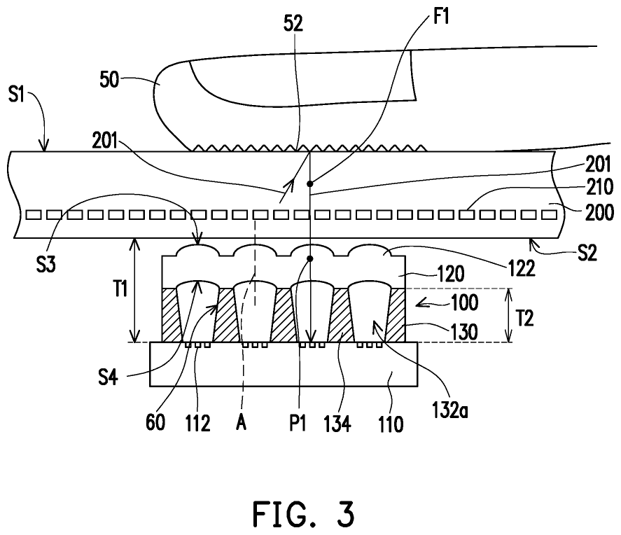

In this embodiment, each light beam 201 coming from one of the microlenses 122 is transmitted to a plurality of corresponding pixels 112 of the image sensor 110 through a corresponding light channel of the light channels 132. For instance, a lower end of each light channel 132 is optically coupled to a plurality of corresponding pixels 112 (e.g., 3×3 pixels or 2×2 pixels). In this embodiment, the light shielding body 134 is a light absorbing body and is, for instance, made of a black material. In this embodiment, the light shielding body 134 is cured liquid silicone rubber, which is formed according to a liquid silicone rubber injection molding technology, for instance. Each light channel 132 may be a transparent space in which air, other gases, or transparent liquids may be distributed, or the transparent space may be a vacuum space. Alternatively, in another embodiment, the ambient light blocking filter is a fiber optical plate, and the light channels 132 are a plurality of transparent solids, respectively. That, the fiber optical plate has a plurality of optical fibers arranged in an array to form the light channels 132, respectively, and the light shielding body 134 fills peripheries of the optical fibers. In this embodiment, each of the light channels 132 may be in a cylindrical shape or in a cuboidal shape. However, in another embodiment, as shown in FIG. 3, each of the light channels 132a may be in a conical shape or in a pyramidal shape.

In the fingerprint sensing module 100 and the electronic apparatus 300 provided in this embodiment, the microlens array 120 is adopted to focus the fingerprint image on the image sensor 110, and the light shielding body 134 of the ambient light blocking filter 130 is applied to prevent the ambient light 60 with a large incident angle (i.e., the ambient light incident obliquely) from being transmitted to the image sensor 110; therefore, the image sensor 110 is allowed to sense an image with a high contrast. In an embodiment, the ambient light blocking filter 130 may filter out incident light that has an included angle of more than 10 degrees with respect to an optical axis A of the microlenses 122. The number of the light channels 132 shown in FIG. 2 is 10×10, for instance, while FIG. 2 is merely a schematic view, and the number of the light channels of the ambient light blocking filter 130 may be M×N, wherein M may be equal to or not equal to N, M and N are both positive integers greater than 1, and in an embodiment, the number of the microlenses 122 may be less than the number of the pixels of the image sensor 110. In addition, since the fingerprint sensing module 100 provided this embodiment adopts the microlens array 120 and the ambient light blocking filter 130 to replace the conventional lenses arranged along the optical axis, the thickness of the fingerprint sensing module 100 may be reduced, so that the electronic apparatus 300 including the display panel 200 and the fingerprint sensing module 100 may be of the reduced thickness. Here, the electronic apparatus 300 is, for instance, a smart phone, a tablet computer, a notebook computer, or other portable electronic apparatuses. In an embodiment, a distance T1 between the display panel 200 and the image sensor 110 is less than 650 micrometers. That is, the electronic apparatus 300 indeed has the reduced thickness, and the fingerprint sensing module 100 provided in this embodiment has the advantages of the reduced thickness and the fingerprint image with relatively high contrast. In an embodiment, a thickness T2 of the ambient light blocking filter 130 falls within a range from 50 micrometers to 250 micrometers.

In this embodiment, the display panel 200 has an upper surface S1 contacted by the finger 50 of a user, a lower surface S2 facing the image sensor 110, and an electrode structure 210 located between the upper surface and the lower surface, and the electrode structure 210 includes non-transparent electrodes existing in the pixel structure of the display panel 200. The microlens array 120 images the fingerprint of the finger contacting the upper surface S1 onto the image sensor 110 but does not image the electrode structure 210 onto the image sensor 110. Thereby, the electrode structure 210 may be prevented from generating moiré interference in the fingerprint image sensed by the image sensor 110. In an embodiment, the electrode structure 210 is located between a principal point P1 of each of the microlenses 122 close to the display panel 200 and a focus F1 close to the display panel 200, and the focus F1 of each of the microlenses 122 close to the display panel 200 is located between the upper surface S1 and the microlenses 122, whereby the effect of imaging the fingerprint of the finger contacting the upper surface S1 onto the image sensor 110 may be achieved, but the effect of imaging the electrode structure 210 onto the image sensor 110 is not achieved. It is added that each of the microlenses 122 has two focuses, one of them is located on a side close to the display panel 200, the other is located on a side close to the image sensor 110, and said focus F1 refers to the focus on the side close to the display panel 200. In addition, each of the microlenses 122 has two principal points, one of them is closer to the display panel 200, the other is closer to the image sensor 110, and said principal point P1 refers to the principal point closer to the display panel 200.

In an embodiment, a surface S3 of each of the microlenses 122 facing the display panel 200 is a convex surface, a surface S4 of each of the microlenses 122 facing the image sensor 110 is a concave surface, and each of the microlenses 122 is a convex lens, while the invention is not limited to what is described herein.

In the fingerprint sensing module and the electronic apparatus provided in the embodiments of the invention, the microlens array is adopted to focus the fingerprint image on the image sensor, and the light shielding body of the ambient light blocking filter is applied to prevent the ambient light with a large incident angle from being transmitted to the image sensor, thereby allowing the image sensor to sense an image with high contrast. In addition, since the microlens array images the fingerprint of the finger contacting the upper surface onto the image sensor but does not image the electrode structure onto the image sensor, the moiré interference of the fingerprint image sensed by the image sensor may be effectively suppressed.

Finally, it should be explained that the above embodiments merely serve to explain the technical solutions of the invention and are not construed as limitations to the invention. Although the invention has been explained in detail with reference to the foregoing embodiments, those of ordinary skill in the art should understand that modifications may be made to the technical solutions described in the foregoing embodiments, or equivalent replacements of some or all of the technical features may be done; however, these modifications or replacements do not cause the essence of the corresponding technical solutions to deviate from the scope of the technical solutions provided in the embodiments of the invention.

What is claimed is:

1. A fingerprint sensing module, characterized in being adapted to be disposed below a display panel and comprising:
an image sensor, disposed below the display panel;
a microlens array, disposed between the image sensor and the display panel and comprising a plurality of microlenses arranged in an array; and
an ambient light blocking filter, disposed between the image sensor and the microlens array and having a plurality of light channels, each of the light channels being surrounded and formed by a light shielding body, wherein light beams coming from the microlenses are respectively transmitted to the image sensor through the light channels,
wherein the display panel has an upper surface contacted by a finger of a user, a lower surface facing the image sensor, and an electrode structure located between the upper surface and the lower surface, and the microlens array images a fingerprint of the finger contacting the upper surface onto the image sensor but does not image the electrode structure onto the image sensor.

2. The fingerprint sensing module according to claim 1, characterized in that each of the light beams coming from one of the microlenses is transmitted to a plurality of corresponding pixels of the image sensor through a corresponding light channel of the light channels.

3. The fingerprint sensing module according to claim 1, characterized in that the image sensor is a thin film transistor image sensor.

4. The fingerprint sensing module according to claim 1, characterized in that the light shielding body is a light absorbing body.

5. The fingerprint sensing module according to claim 1, characterized in that the ambient light blocking filter is a fiber optical plate.

6. The fingerprint sensing module according to claim 1, characterized in that the light channels are a plurality of transparent solids, respectively.

7. The fingerprint sensing module according to claim 1, characterized in that the light shielding body is cured liquid silicone rubber.

8. The fingerprint sensing module according to claim 1, characterized in that the light channels are a plurality of transparent spaces, respectively.

9. The fingerprint sensing module according to claim 1, characterized in that each of the light channels is in a cylindrical shape, in a cuboidal shape, in a conical shape, or in a pyramidal shape.

10. The fingerprint sensing module according to claim 1, characterized in that the electrode structure is located between a principal point of each of the microlenses close to the display panel and a focus of each of the microlenses close to the display panel, and the focus of each of the microlenses close to the display panel is located between the upper surface and the microlenses.

11. An electronic apparatus, characterized in comprising:
a display panel; and
a fingerprint sensing module, disposed below the display panel and comprising:
an image sensor, disposed below the display panel;
a microlens array, disposed between the image sensor and the display panel and comprising a plurality of microlenses arranged in an array; and
an ambient light blocking filter, disposed between the image sensor and the microlens array and having a plurality of light channels, each of the light channels being surrounded and formed by a light shielding body, wherein light beams coming from the microlenses are respectively transmitted to the image sensor through the light channels,
wherein the display panel has an upper surface contacted by a finger of a user, a lower surface facing the image sensor, and an electrode structure located between the upper surface and the lower surface, and the microlens array images a fingerprint of the finger contacting the upper surface onto the image sensor but does not image the electrode structure onto the image sensor.

12. The electronic apparatus according to claim 11, characterized in that each of the light beams coming from one of the microlenses is transmitted to a plurality of corresponding pixels of the image sensor through a corresponding light channel of the light channels.

13. The electronic apparatus according to claim 11, characterized in that the image sensor is a thin film transistor image sensor.

14. The electronic apparatus according to claim 11, characterized in that the light shielding body is a light absorbing body.

15. The electronic apparatus according to claim 11, characterized in that the ambient light blocking filter is a fiber optical plate.

16. The electronic apparatus according to claim 11, characterized in that the light channels are a plurality of transparent solids, respectively.

17. The electronic apparatus according to claim 11, characterized in that the light shielding body is cured liquid silicone rubber.

18. The electronic apparatus according to claim 11, characterized in that the light channels are a plurality of transparent spaces, respectively.

19. The electronic apparatus according to claim 11, characterized in that each of the light channels is in a cylindrical shape, in a cuboidal shape, in a conical shape, or in a pyramidal shape.

20. The electronic apparatus according to claim 11, characterized in that the electrode structure is located between a principal point of each of the microlenses close to the display panel and a focus of each of the microlenses close to the display panel, and the focus of each of the microlenses close to the display panel is located between the upper surface and the microlenses.
